(19) United States
(12) Patent Application Publication
(10) Pub. No.: US 2020/0027755 A1
(43) Pub. Date: Jan. 23, 2020

(54) TEMPORARY-FIXING SUBSTRATE AND METHOD FOR MOLDING ELECTRONIC COMPONENT

(71) Applicant: NGK INSULATORS, LTD., Nagoya-City (JP)

(72) Inventors: Masaru NOMURA, Owariasahi-City (JP); Sugio MIYAZAWA, Kasugai-City (JP)

(21) Appl. No.: 16/585,089

(22) Filed: Sep. 27, 2019

Related U.S. Application Data
(63) Continuation of application No. PCT/JP2018/003404, filed on Feb. 1, 2018.

(30) Foreign Application Priority Data
Mar. 30, 2017 (JP) 2017-066793

(51) Int. Cl. H01L 21/56; H01L 21/321

(52) U.S. Cl. CPC H01L 21/565; H01L 21/3212; H01L 21/568

(57) ABSTRACT

A temporary-fixing substrate includes a fixing face for adhering and temporary-fixing a plurality of electronic parts with a resin mold and a bottom face on the opposite side of the fixing face. The temporary-fixing substrate is composed of a translucent ceramic material, scratches are distributed on the fixing face, and intergranular boundaries and polished surfaces of crystal grains forming the translucent ceramic material are exposed to the bottom face. The density of scratches on the bottom face is lower than the density of scratches on the fixing face.

### CROSS-REFERENCE TO RELATED APPLICATIONS

This application is a continuation application of PCT/JP2018/003404, filed Feb. 1, 2018, which claims priority to Japanese Application No. 2017-066793, filed Mar. 30, 2017, the entire contents all of which are incorporated hereby by reference.

### TECHNICAL FIELD

The present invention relates to a temporary-fixing substrate including a fixing face for adhering and temporary-fixing electronic parts with a resin mold and a bottom face on the opposite side of the fixing face.

### BACKGROUND ARTS

It is known a method of adhering and fixing electronic parts made of silicon or the like on a supporting body made of a glass or ceramic (Patent documents 1, 2 and 3). According to such related arts, electronic parts are adhered to a supporting body with a thermal curable resin and then cooled to obtain a bonded body. In this case, it is tried to adjust the warpage of the supporting body to reduce the warpage of the bonded body. Further, the warpage of the supporting body is adjusted by changing a method of polishing or by removing the processing denatured layer.

Further, according to patent document 4, it is disclosed the following. That is, when a light-emitting diode is mounted on a surface of a sapphire substrate, first and second main faces of the sapphire substrate are polished by lapping and only the first main face is subjected to precise polishing by CMP or the like.

### RELATED TECHNICAL DOCUMENTS

### Patent Documents

(Patent document 1) Japanese Patent publication No. 2011-023438A
(Patent document 2) Japanese Patent publication No. 2010-058989A
(Patent document 3) Japanese Patent No. 5304112B
(Patent document 4) Japanese Patent publication No. 2016-139751A
(Patent document 5) WO 2014-199975 A1

### SUMMARY OF THE INVENTION

The present inventors researched to adhere and temporary fix many electronic parts on a temporary-fixing substrate made of a translucent ceramic with a resin mold, and to irradiate light from the side of the bottom face of the temporary-fixing substrate, so that the electronic parts and resin mold are separated from the temporary-fixing substrate. During the process, it has been researched the application of various kinds of supporting bodies described in related arts.

However, in the case that a plurality of the electronic parts is adhered and then temporary-fixed on the temporary-fixing substrate with the resin mold and that the electronic parts are separated from the temporary-fixing substrate by light irradiation. unique problems are proved to be provided. That is, after the electronic parts are adhered onto the temporary-fixing substrate, liquid resin mold agent is flown and then solidified by heating, so that the electronic parts are fixed in the resin mold. Then, ultraviolet light is irradiated from the side of the temporary-fixing substrate to separate the resin mold and temporary-fixing substrate, so that the electronic parts are separated from the temporary-fixing substrate with the resin mold.

However, when light is irradiated from the side of the temporary-fixing substrate, a ratio of the light reaching an interface between the temporary-fixing substrate and electronic parts is proved to be low, resulting in a low yield of separation in many cases. On the other hand, in the case that the ratio of the light reaching the interface between the temporary-fixing substrate and electronic parts is raised, the adhesion of the temporary-fixing substrate and electronic parts is strong, so that the separation is suppressed in a part of the substrate. The yield of the separation is proved to be also low.

An object of the present invention is, in adhering and temporary-fixing electronic parts on a fixing face of a temporary-fixing substrate with a resin mold and irradiating light from the side of a bottom face to separate the electronic parts and resin mold from the temporary-fixing substrate, to improve a yield of the step of separation.

The present invention provides a temporary-fixing substrate comprising a fixing face for adhering and temporary fixing a plurality of electronic parts by a resin mold on the fixing face and a bottom face on the opposite side of the fixing face;

wherein the temporary-fixing substrate comprises a translucent ceramic material;

wherein scratches are distributed on the fixing face; wherein the translucent ceramic material comprises crystal grains having polished surfaces, respectively, and grain boundaries, the polished surfaces and grain boundaries being exposed to the bottom face; and

wherein a density of scratches on the bottom face is lower than a density of scratches on the fixing face.

The present invention further provides a method of molding electronic parts, the method comprising the steps of:

lapping a first main face and a second main face of a base material comprising a translucent ceramic material;

then subjecting the second main face to chemical mechanical polishing to obtain a temporary-fixing substrate having a fixing face and a bottom face;

then adhering the electronic parts on the fixing face of the temporary-fixing substrate with a resin mold; and

irradiating a light from a side of the bottom face to separate the electronic parts and the resin mold from the temporary-fixing substrate.

In the case that electronic parts are adhered and temporarily-fixed onto a fixing face of a temporary-fixing substrate with a resin mold and light is irradiated from the side of a bottom face to separate the electronic parts and resin mold from the temporary-fixing substrate, the inventors have researched the cause of the difficulty of the separation During the process, the inventors gave attention to the difference of the surface state of the fixing face and that of the bottom face of the temporary-fixing substrate and then researched the processing method. During the research, it is found that the yield of the separation of the electronic parts and resin mold from the temporary-fixing substrate by light irradiation is improved, by subjecting the fixing face of the temporary-fixing substrate to lapping and the bottom face to lapping followed by chemical mechanical polishing (CMP).

As to the above points, the fixing face and bottom face of the thus obtained temporary-fixing substrate are further researched microscopically. As a result, as the fixing face is subjected to lapping, it is proved that many scratches are randomly distributed. On the other hand, the bottom face is subjected to lapping followed by chemical mechanical polishing, so that the polished surfaces of the crystal grains forming the translucent ceramic material and the grain boundaries are exposed to the surface. Thus, there is distributed regions in which the scratches are relatively rich and non-distributed regions in which the scratches are not present or hardly present. The reasons may be considered as follows. As the crystal orientations of the crystal grains are different from each other, scratches disappear in the crystal grains with the etching being proceeded as the polishing proceeds, and scratches are left in the crystal grains with the etching not being effectively proceeded.

Light is then irradiated onto the bottom face of the temporary-fixing substrate. As the scratches are decreased on the bottom face and the polished surfaces of the crystal grains and grain boundaries are exposed to the bottom face, the light is relatively easily made incident into the substrate. On other hand, as many scratches are distributed on the fixing face of the temporary-fixing substrate, it is considered that the adhesion of the temporary-fixing substrate and the adhesive layer is interrupted microscopically so that they can be easily separated from each other.

### BRIEF DESCRIPTION OF THE DRAWINGS

FIG. 1(a) shows a base material 2A, FIG. 1(b) shows the state that main faces 1A and 3A of a base material 2B are subjected to lapping, and FIG. 1(c) shows a temporary-fixing substrate 2.

FIG. 2(a) shows the state that an adhesive 4 is provided on the fixing face 1A of the temporary-fixing substrate 2, and FIG. 2(b) shows the state that electronic parts 6 are adhered onto the fixing face 1A of the temporary-fixing substrate 2.

FIG. 3(a) shows the state that the electronic parts 6 are temporary-fixed with a resin mold 7, and FIG. 3(b) shows the state that the electronic parts 6 and resin mold 7 are separated from the temporary-fixing substrate by irradiation of light.

FIG. 4 shows a photograph of a fixing face taken by a microscope.

FIG. 5 shows a photograph of a fixing face taken by a microscope of a bottom face.

FIG. 6 shows an example of a profile of a cross section of a fixing face of a temporary-fixing substrate.

FIG. 7 shows an example of a profile of a cross section of a fixing face of a temporary-fixing substrate.

FIG. 8 shows an example of a profile of a cross section of a fixing face of a temporary-fixing substrate.

### EMBODIMENTS FOR CARRYING OUT THE INVENTION

The present invention will be further described in detail, appropriately referring to the attached drawings.

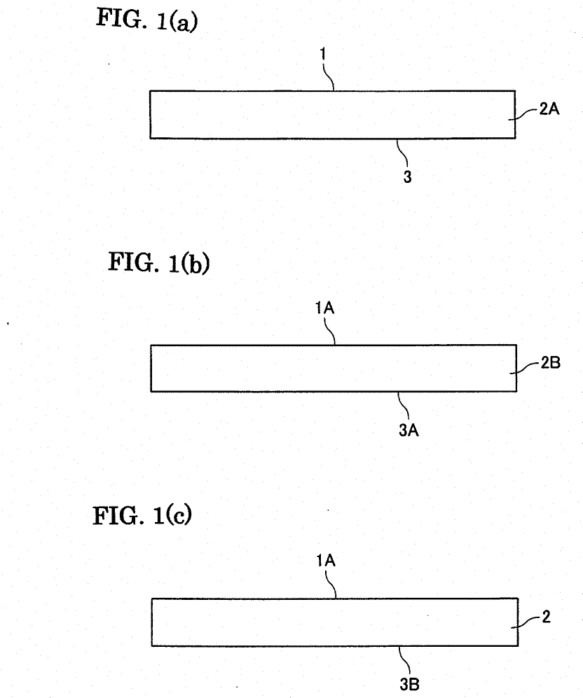

As shown in FIG. 1(a), a base material 2A has a first main face 1 and second main face 3. The base material 2A is composed of a translucent ceramic material.

The translucent ceramic material in the specification means a ceramic material having a total forward light transmittance of 20% or higher in whole wavelength range of 200 to 1500 nm. The total forward light transmittance in the specification means that measured according to the same procedure as that described in [0064] of WO 2014-199975A1. Further, the measured wavelength range is made 200 to 1500 nm.

The translucent ceramic material includes translucent alumina, silicon nitride, aluminum nitride and silicon oxide. The densities of the materials can be easily made high and the resistance against chemicals is high.

According to a preferred embodiment, the material of the temporary-fixing substrate is translucent alumina. In this case, preferably, 100 ppm more and 300 ppm or less of magnesium oxide is added to high-purity alumina powder having a purity of 99.9 percent or higher (preferably 99.95 percent or higher). Such high-purity alumina powder includes high-purity alumina powder produced by Taimei Chemical Industries Corporation. Further, the purity and average grain size of the magnesium oxide powder may preferably be 99.9 percent or higher and 50 μm or smaller, respectively.

According to a preferred embodiment, to the alumina powder, 200 to 800 mass ppm of zirconia (ZrO₂), and 10 to 30 mass ppm of yttria (Y₂O₃) are added as sintering aids.

The method of molding the temporary-fixing substrate is not particularly limited, and may be an optional process such as doctor blade, extrusion, gel cast molding or the like. Most preferably, the temporary-fixing substrate is produced utilizing gel cast molding.

According to a preferred embodiment, slurry containing ceramic powder, dispersing agent and gelling agent are cast into a mold, and the slurry is then gelled to obtain a molded body. During the gel cast molding, a releasing agent is applied onto mold parts, the mold parts are constructed and the slurry is injected. Then, the gel is solidified in the mold to obtain the molded body, which is then released from the mold. The mold is then washed.

Next, the gel molded body is dried, preferably, calcined in air, and then sintered in hydrogen. The sintering temperature in this sintering process is preferably in a range of 1700 to 1900° C., and more preferably in a range of 1750 to 1850° C. in terms of densification of the sintered body.

After generating the fully-dense sintered body in the sintering process, further an annealing treatment may be additionally performed, which can control or correct the warpage of the substrate. From the viewpoint of promoting the discharge of the sintering aids while preventing deformation and occurrence of abnormal grain growth, the annealing temperature is preferably within a range of the maximum temperature in the sintering ±100° C., in which the maximum temperature is more preferably 1900° C. or lower. The annealing time period is preferably in a range of 1 to 6 hours.

Then, the first main face and second main face of the base material composed of the translucent ceramic material is subjected to lapping. That is, as shown in FIG. 1(b), the first main face 1 and second main face 3 are subjected to lapping to form lapped surfaces 1A and 3A.

For the lapping, it is used aqueous or oily diamond slurry. As the material of the surface plate, it is used copper, resin copper, tin or the like, or it is used a metal surface plate with a polishing pad adhered thereon. The polishing pad includes a hard urethane pad, a non-woven pad and suede pad.

The second main face 3A is then subjected to chemical mechanical polishing to obtain the temporary-fixing substrate 2 having the fixing face 1A and bottom face 3B (FIG. 1(c)). At this stage, the first main face 1A is not subjected to chemical mechanical polishing and is left as the lapped surface.

As to the chemical mechanical polishing, it is used polishing slurry containing an alkaline or neutral solution with abrasives having a particle size of 30 nm to 200 nm dispersed therein. As the material of the abrasives, silica, alumina, diamond, zirconia and ceria may be listed and used alone or in combination. Further, the polishing pad includes a hard urethane pad, a non-woven pad and suede pad.

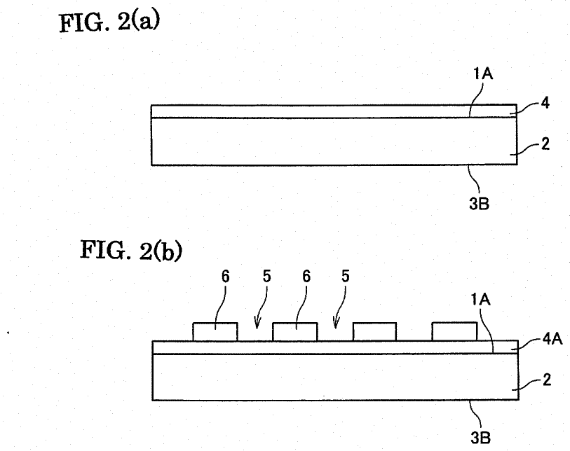

The electronic parts are adhered onto the fixing face of the temporary-fixing substrate to temporary fix the electronic parts with the resin mold. For example, as shown in FIG. 2(a), the adhesive layer 4 is provided on the fixing face 1A of the temporary-fixing substrate 2.

Such adhesive includes a double-sided tape or a hot-melt-based adhesive. Further, as the method of providing the adhesive layer on the temporary-fixing substrate, it may be applied various methods including roll application, spray application, screen printing, spin coating and the like.

Then, as shown in FIG. 2(b), many electronic parts 6 are mounted on the temporary-fixing substrate 2 and the adhesive layer is solidified to form an adhesive layer 4A. The solidifying step is carried out depending on the nature of the adhesive and includes heating or irradiation of ultraviolet light.

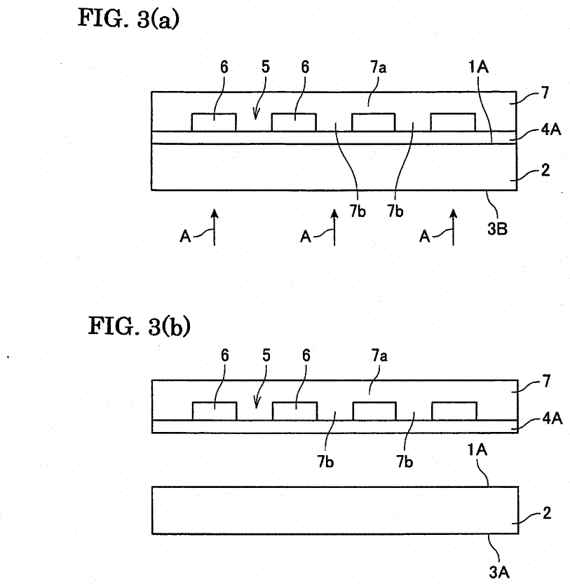

Then, the liquid resin mold is flown and then solidified. By this, as shown in FIG. 3(a), the electronic parts 6 are fixed in the resin mold 7. Further, 7b represents a resin filling spaces 5 between the electronic parts and 7a represents a resin covering the electronic parts.

The molding resin used in the present invention includes epoxy resin, polyimide resin, polyurethane resin, urethane resin and the like.

Then, as shown in arrows A, light is irradiated from the side of the bottom face 3B of the temporary-fixing substrate 2 to separate the electronic parts 6 and resin mold 7 from the temporary-fixing substrate (refer to FIG. 3(b)).

The wavelength of the light irradiated from the side of the temporary-fixing substrate is appropriately changed depending on the kind of the electronic part or resin mold, and may be made 200 nm to 400 nm, for example.

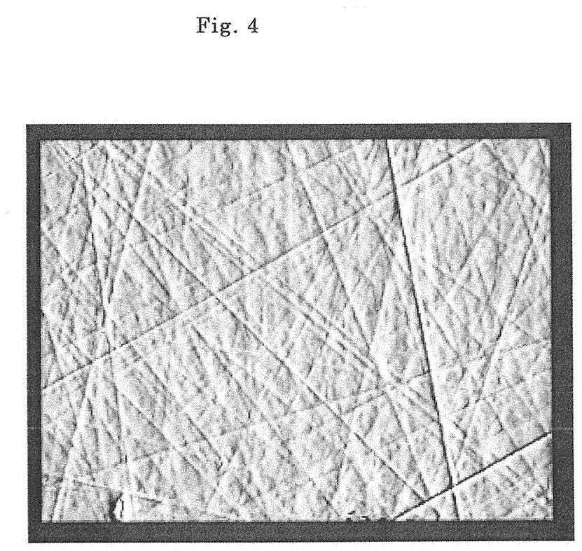

Here, scratches provided by the lapping are distributed on the fixing face of the temporary-fixing substrate to provide scratch-distributed face. For example, as shown in FIG. 4, intergranular boundaries are not observed and many scratches are elongated on the fixing face. According to such surface morphology, the adhesion of the temporary-fixing substrate and adhesive layer is appropriately reduced so that they are easily separated upon the irradiation of the light.

Here, for observing the crystal grains and intergranular boundaries on the fixing face, it is used an optical microscope of a magnitude of 500. Further, for observing the density of the scratches on the fixing face, it is used an optical system surface morphology measuring equipment “Zygo NV7300” (supplied by Canon corporation). Then, the visual field of the observation is made a rectangular visual field of 70 μm (longest axis) and 50 μm (shortest axis). The presence or absence of the scratches is judged as follows.

That is, “a recess having a depth of 5 nm or larger and a recess diameter of 10 μm or smaller” is judged as the scratch, in a profile (cross section) in the direction of the longest axis obtained by the measurement of the fixing face.

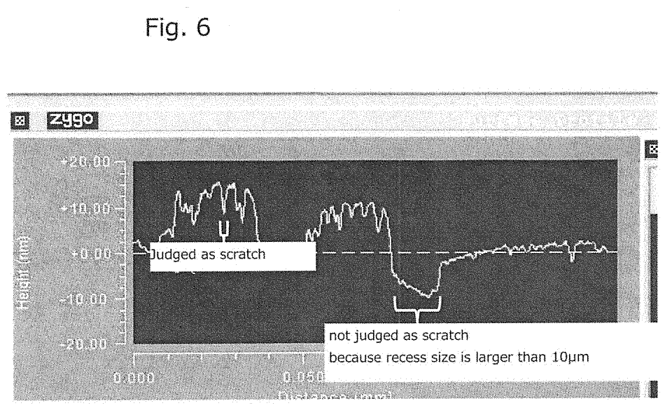

For example, as shown in FIG. 6, the recess on the left side has a recess diameter of 10 μm or less and thus judged as the scratch. On the other hand, a recess on the right side has a recess diameter larger than 10 μm and thus is not judged as the scratch.

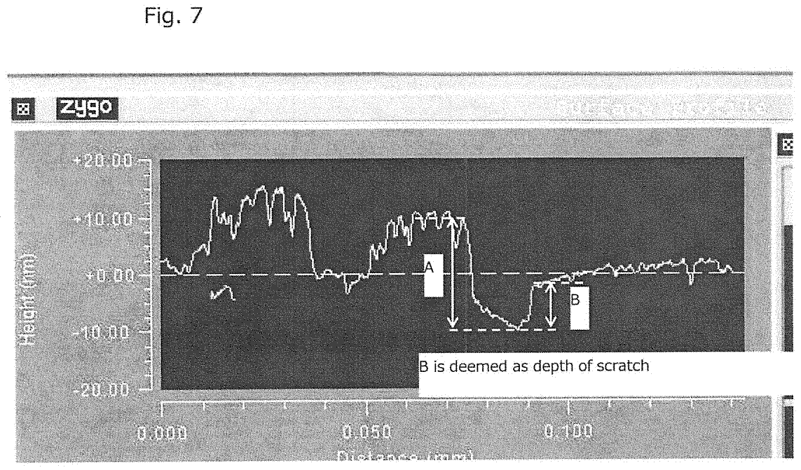

Further, in the case that both shoulders of the recess have heights different from each other, the depth is defined as a distance between the bottom of the recess and one shoulder which is nearer to the bottom of the recess. For example, according to an example shown in FIG. 7, A is assigned to a height of the shoulder on the left side and B is assigned to the height of the shoulder on the right side with respect to the bottom of the recess, and B is smaller than A. In this case, B is assigned to the depth of the recess.

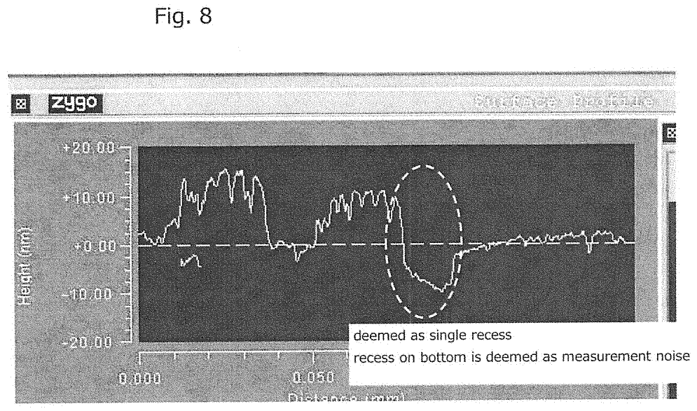

Further, a recess having a depth less than 5 nm is deemed as fine unevenness or noise on the surface and is not to be counted as the scratch according to the judgement, and it is deemed that both shoulders are smoothly connected. For example, a recess shown in FIG. 8 has a depth less than 5 nm, so that it is not judged as the scratch.

Under such condition, the scratch density is defined as a number of the scratches observed in a profile in the direction of the longest axis in a central part viewed in the direction of the shortest axis, in the rectangular visual field of 70 μm and 50 μm. The density of the scratches on the fixing face may preferably be 10 to 50 lines and more preferably be 20 to 40 lines.

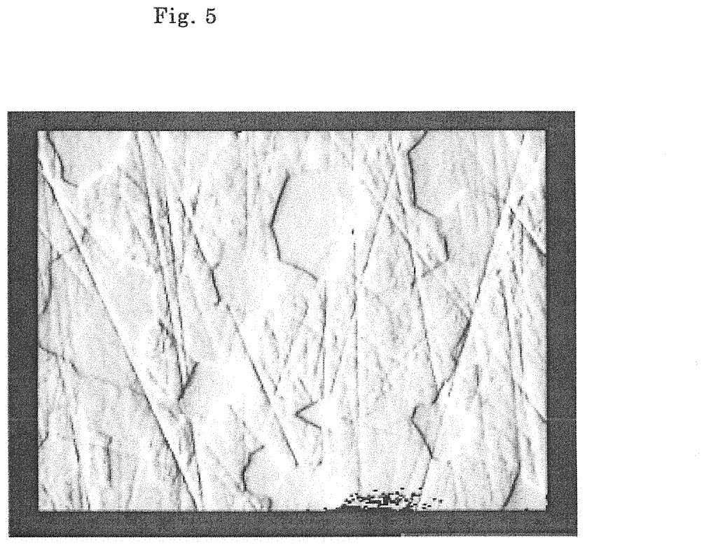

Further, on the bottom face, for example as shown in FIG. 5, the intergranular boundaries and polished surfaces of the crystal grains forming the translucent ceramic material are exposed to the bottom face. Then, the bottom face includes distributed regions in which the scratches are distributed and non-distributed regions in which the scratches are not distributed or only a few scratches are distributed.

Further, the procedure of observing the bottom face is made same as that of the fixing face. Further, the density of the scratches observed in the visual field may preferably be 8 lines or less and the scratches may not be observed.

### EXAMPLES

### Inventive Example 1

It was produced the temporary-fixing substrate, and the electronic parts and resin mold were separated from the temporary-fixing substrate, as shown in FIGS. 1 to 3.

Specifically, it was produced slurry by mixing the following components.

### (Powdery Raw Material)

α-alumina powder having a specific surface area of 3.5 to 4.5 m²/g and an average primary particle size of 0.35 to 0.45 μm

| | 100 weight parts |
|---|---|
| MgO (magnesia) | 0.025 weight parts |
| ZrO₂ (zirconia) | 0.040 weight parts |
| Y₂O₃ | 0.0015 weight parts |

### (Dispersing Medium)

| | |
|---|---|
| Dimethyl glutarate | 27 weight parts |
| Ethylene glycol | 0.3 weight parts |

### (Gelling Agent)

| | |
|---|---|
| MDI resin | 4 weight parts |

### (Dispersing Agent)

| | |
|---|---|
| High molecular surfactant | 3 weight parts |

### (Solvent)

| | |
|---|---|
| N,N-dimethyl amino hexanol | 0.1 weight parts |

The slurry was injected into a mold of aluminum alloy at room temperature and then stood for 1 hour at room temperature. The slurry was then stood at 40° C. for 30 minutes to proceed the solidification and then released from the mold. Further, it was stood at room temperature for 2 hours and then at 90° C. for 2 hours to obtain a plate-shaped powdery molded body.

The thus obtained powdery molded body was calcined (preliminary sintering) in atmosphere at 1100° C., and sintered in atmosphere of hydrogen and nitrogen in a ratio of 3:1 at 1750° C. Thereafter, annealing treatment was performed under the same condition to obtain a base material 2A.

The first main face and second main face of the thus produced material 2A were subjected to double-sided lapping with diamond slurry. The grain size of the diamond was made bpm. Then, only the second main face 3A was subjected to chemical mechanical polishing with SiO₂ abrasives and diamond abrasives, followed by washing to obtain the temporary-fixing substrate 2 (refer to FIG. 1(c)) having 9 of 300 mm and a thickness of 0.85 mm. The first main face 1A was not subjected to the chemical mechanical polishing.

Here, the grain boundaries of the crystal grains were not observed and scratches due to the lapping were distributed on the fixing face 1A, providing the scratch distributed face. The number of the scratches observed in the rectangular visual field of 70 μm×50 μm was proved to be 30. Further, on the bottom face, the grain boundaries and polished surfaces of the crystal grains forming the translucent alumina were exposed to the bottom face, and it was observed the distributed regions in which the scratches are distributed and non-distributed regions in which the scratches are not distributed. The line number of the scratches observed in the visual field was proved to be 3 lines.

Adhesive (UV separation tape, “SELFA-SE” (supplied by SEKISUI CHEMICAL CO., LTD.) was then applied on the fixing face 1A of the temporary-fixing substrate, and 7500 counts of electronic parts each having dimensions of 2 mm×2 mm were regularly positioned. It was then heated at 200° C. to solidify the adhesive. Mold resin (“R4212-2C” (supplied by Nagase ChemteX Corporation) was then flown and heated for the solidification so that the electronic parts were fixed with the resin mold.

Ultraviolet ray was then irradiated from the side of the bottom face of the temporary-fixing substrate. As a result, the yield was proved to be 99.5% in the step of separating the electronic parts and resin mold from the temporary-fixing substrate.

### Inventive Example 2

It was produced the temporary-fixing substrate and the electronic parts and resin mold were separated from the temporary-fixing substrate, according to the same procedure as those in the Inventive Example 1. However, the time period of performing the chemical mechanical polishing of the bottom face was shortened so that the line number of the scratches observed in the visual field was made 5 lines. As a result, the yield of the separation of the electronic parts and resin mold was proved to be 99.3%.

### Inventive Example 3

It was produced the temporary-fixing substrate, and the electronic parts and resin mold were separated from the temporary-fixing substrate, according to the same procedure as the inventive Example 1. However, the time period of the chemical mechanical polishing of the bottom face is made longer, so that the line number of the scratches observed in the visual field was proved to be 0. As a result, the yield of the separation of the electronic parts and resin mold was proved to be 99.5%.

### Comparative Example 1

It was produced the temporary-fixing substrate, and the electronic parts and resin mold were separated from the temporary-fixing substrate, according to the same procedure as those in the Inventive Example 1. However, different from the Inventive Example 1, the chemical mechanical polishing of the second main face was not performed. As a result, the state of the fixing face was proved to be same as that of the bottom face, and the numbers of the scratches in the visual fields were 30 on both faces. The yield of the separation of the electronic parts and resin mold from the temporary-fixing substrate was proved to be 93.2%. It is considered that a sufficient amount of the ultraviolet ray did not reach the interface of the adhesive layer and temporary-fixing substrate so that the efficiency of utilization of the light was reduced.

### Comparative Example 2

The temporary-fixing substrate was produced, and the electronic parts and resin mold were separated from the temporary-fixing substrate, according to the same procedure as the Inventive Example 1. However, different from the Inventive Example 1, both of the first main face and second main face were subjected to chemical mechanical polishing. As a result, the state of the fixing face was proved to be same as that of the bottom face, and both of the numbers of the scratches in the visual fields were 3, respectively. The yield of the separation of the electronic parts and resin mold was proved to be 94.2%. It is considered that the adhesion of the temporary-fixing substrate and adhesive layer was strong so that the separation did not proceed smoothly.

What is claimed is:

1. A temporary-fixing substrate comprising a fixing face for adhering and temporary fixing a plurality of electronic parts with a resin mold on said fixing face and a bottom face on an opposite side of said fixing face;
wherein said temporary-fixing substrate comprises a translucent ceramic material;
wherein scratches are distributed on said fixing face; wherein said translucent ceramic material comprises crystal grains having polished surfaces, respectively, and grain boundaries, said polished surfaces and grain boundaries being exposed to said bottom face; and
wherein a density of scratches on said bottom face is lower than a density of scratches on said fixing face.

2. The temporary-fixing substrate of claim 1, wherein said fixing face comprises a lapped surface, and wherein said bottom face comprises a surface subjected to lapping and chemical mechanical polishing.

3. The temporary-fixing substrate of claim 1, wherein said translucent ceramic material comprises a translucent alumina.

4. A method of molding electronic parts, the method comprising the steps of:
lapping a first main face and a second main face of a base material comprising a translucent ceramic material;
then subjecting said second main face to chemical mechanical polishing to obtain a temporary-fixing substrate having a fixing face and a bottom face;
then adhering and temporary fixing said electronic parts on said fixing face of said temporary-fixing substrate with a resin mold; and
irradiating a light from a side of said bottom face to separate said electronic parts and said resin mold from said temporary-fixing substrate.

5. The method of claim 4, wherein said translucent ceramic material comprises translucent alumina.
